(19) United States
(12) Patent Application Publication
(10) Pub. No.: US 2026/0211344 A1
(43) Pub. Date: Jul. 23, 2026

(54) SEMICONDUCTOR LITHOGRAPHY APPARATUS FOR MEASURING AND/OR REGISTERING STRUCTURES AND METHODS FOR MEASURING AND/OR REGISTERING STRUCTURES

(71) Applicant: Carl Zeiss SMT GmbH, Oberkochen (DE)

(72) Inventors: Roman Schmeissner, Weimar (DE); Ulrich Matejka, Jena (DE); Uwe Horn, Rudolstadt (DE)

(21) Appl. No.: 19/453,328

(22) Filed: Jan. 20, 2026

(30) Foreign Application Priority Data
Jan. 22, 2025 (DE) 102025102260.7

(51) Int. Cl. G03F 9/00; G03F 1/42; G03F 7/00; G06T 7/00; G06T 7/60

(52) U.S. Cl. CPC G03F 9/7069; G03F 1/42; G03F 7/70625; G03F 7/706837; G03F 7/706839; G03F 7/706851; G03F 9/7092; G06T 7/001; G06T 7/60; G06T 2207/30148

(57) ABSTRACT

The disclosure relates to a semiconductor lithography apparatus and method for measuring and/or registering structures on an object by means of illumination and an optical unit for illuminating the structure. The apparatus and method are distinguished in that the illumination is in the form of dark field illumination.

### CROSS REFERENCE TO RELATED APPLICATIONS

The present application claims the priority of the German patent application 10 2025 102 260.7, filed on Jan. 22, 2025, the content of which is fully incorporated by reference herein.

### TECHNICAL FIELD

The disclosure relates to a semiconductor lithography apparatus for measuring and/or registering structures and to a method for measuring and/or registering structures.

### BACKGROUND

In semiconductor technology, various processes are combined for producing microstructured components, such as integrated circuits or LCDs (liquid crystal displays). The processes include, inter alia, the production and qualification of objects in the form of photolithographic masks, which are also referred to as photomasks or simply masks, and the production of objects in the form of substrates, in particular wafers, and the qualification thereof. This usually involves measuring and/or registering subregions with the structures or structure elements to be measured. Registration is a determination of a position of a structure or structure element on the mask, where the position is determined relative to a reference.

Furthermore, the critical dimension of the structure or structure element can also be determined on the basis of the positions of individual structures or determined positions of the contour of a structure. Both pieces of information are essential for subsequent processes in the production of integrated circuits.

In the central so-called lithography process or microlithography process, the mask is illuminated in a projection exposure apparatus by an illumination unit. The light passing through the mask or the light reflected by the mask is projected, by means of a projection optical unit, onto a substrate (for example a wafer), which is coated with a light-sensitive layer (photoresist) and mounted in the image plane of the projection optical unit, in order to transfer the structure elements of the mask to the light-sensitive coating of the substrate. The structure transferred in this way to the substrate is formed in an electrically conductive material in a further process step. A microstructured component usually comprises between 20 and 50 of these layers, which cooperate to form a three-dimensional component. The process described above is thus repeated multiple times. An error, for example a structure positioning error, that is to say displacement of the structure on the mask with respect to a position stipulated during design and/or a deviation in a critical dimension of the structure, can lead to the failure of the entire electrical component during production, which is why the masks and the wafers are checked for possible defects in inspection processes by means of so-called mask or wafer inspection apparatuses.

The structure elements must therefore be positioned very accurately on the surface of masks so that the permissible deviations from the predetermined positions thereof or deviations from a critical dimension of a structure element are in the nanometre range, preferably in the sub-nanometre range, so as not to lead to errors on wafers during the exposure with the corresponding mask. Photomasks that can meet these requirements are produced by high-precision mask writer. The calibration and monitoring of the written geometries and distances must be performed by suitable measuring systems. In particular, there are high demands on the measuring system, since a ratio of 1:5 to 1:10 between measurement accuracy and device tolerance is typically required. Another measurement task in the photomask production process is the exact position measurement of defects. This makes it possible to repair or treat said defects.

Measuring devices, for example mask inspection microscopes, are used for the examination of positioning errors, critical dimensions and the exact positioning of defects. Mask inspection microscopes use electromagnetic radiation with a wavelength greater than or equal to 193 nm for imaging. The mask inspection microscopes known from the prior art can therefore currently only resolve line widths up to a minimum width of 80 nm. The requirements to use increasingly smaller structures, especially in EUV lithography, which uses a wavelength of 13.5 nm to image the structures, result in this resolution limit being exceeded.

To increase the resolution, the only available option is to increase the numerical aperture of the mask inspection microscope or decrease the wavelength used for imaging.

The increase in the numerical aperture is physically limited or can only be realized with a very high development effort.

The use of a wavelength of 13.5 nm in a mask inspection microscope is currently not possible because, for a radiation with 13.5 nm, no transmitting optical elements are available, only reflecting ones. A beam splitter used in the known mask inspection microscopes for realizing a vertical beam incidence on the mask is currently unavailable in the required quality and stability. This means that only non-vertical angles of incidence can be realized.

The oblique illumination used in EUV lithography projection exposure apparatuses with an illumination angle of, for example, 6° has the disadvantage that focus errors affect a positioning error with a factor of the tangent of the illumination angle. This results in requirements for the focus accuracy of a mask registration microscope with oblique illumination of less than 1 nm in order to achieve a required registration measurement accuracy of 0.1 nm. These accuracies cannot be ensured in current systems.

Another disadvantage is that EUV masks known from the prior art only reflect the radiation up to an angle of approximately 12°. This corresponds to a numerical aperture of approximately 0.20. Outside an angle of 12°, the reflection rapidly decreases very significantly, which negatively affects the imaging accuracy. In other words, the measurement is limited to a numerical aperture of 0.20.

In a cone with a radius of 12°, the illumination beam path and the imaging beam path would therefore have to find space, thus reducing the mask-side numerical aperture even below the elucidated 0.20. For the mask registration microscope, the lower numerical aperture causes an adverse reduction in the resolution.

### SUMMARY

Disclosed herein are embodiments of a device and method for determining the geometry and/or registration of a structure. The embodiments are directed to eliminating at least some of the disadvantages of the prior art described above.

In a first aspect, disclosed is a semiconductor lithography apparatus for measuring and/or registering structures on an object using an illumination for illuminating the structure and an optical unit for imaging the structure, wherein the illumination is in the form of dark field illumination. The principle of dark field illumination in microscopy is based on the fact that objects not only absorb or reflect light, but also always deflect part of the light beam. If the illumination is set so that the direct light beams emitted by the object, i.e. the zeroth order of diffraction, pass by the microscope objective, the viewer sees only the deflected light. One of the causes of deflection is the scattering of light on small particles, known as the Tyndall effect, which can also be observed, for example, when light falls into a dark room and a dust particle within the light beam becomes clearly visible.

In dark field illumination, the Oth order of diffraction is not captured by the imaging optical unit and is therefore not imaged onto the image plane or camera plane. The contrast of the acquired image is caused by interference between the other orders of diffraction, such as the 1st with the 2nd order of diffraction or the 1st with the −1st order of diffraction. Uniform surfaces of the object (whether light or dark) always appear dark in the image plane in the case of dark field illumination. On the other hand, the edges between light and dark surfaces of the object appear bright in the image plane.

In certain embodiments, the wavelength used for illuminating the structure may be in a range of from 5 to 100 nm, in particular may be 13.5 nm. The wavelength used in EUV lithography has the advantage that the resolution of the apparatus is increased compared to a wavelength of 193 nm used in the prior art and thus smaller lines can be resolved.

In addition, the wavelength used for illuminating the structure may be in a range of from 100 nm to 300 nm, in particular may be 193 nm. The use of the wavelength of 193 nm used in DUV lithography has the advantage that transmitting optical elements can be used.

Furthermore, the scattered light used in the dark field can also be used to achieve a higher resolution. This is due to the effect that even structures below the resolution limit of the optical image can scatter light. This can advantageously be used, in particular, to improve the contrast of mask defects below the resolution limit of the measuring microscope. In particular, this application possibility is aimed at the registration of defects with sizes below 50 nm on EUV masks using DUV mask registration microscopes.

In certain embodiments, the illumination may be rotationally symmetrical or at least point-symmetrical about the surface normals of the object. The point-symmetrical arrangement has the advantage that a displacement of the object in the z-direction, i.e. in the direction of the beam path, does not cause any displacement of the structure in the x-y plane of the image. The structure is only presented with more or less sharpness. In particular, this has the advantage that, regardless of the position in the z-direction, the centre of the structure that is relevant to the registration of the structure is not displaced in the x-y plane. The z-position of the object therefore has no influence on the accuracy of the registration of the structure in the first approximation.

In particular, the illumination may take the form of discrete illumination. The illumination may therefore also comprise, for example, two, four, six or eight poles arranged, in particular, point-symmetrically.

Furthermore, the illumination may take the form of continuous, rotationally symmetrical illumination. This may take the form, for example, of a so-called ring illumination known from classical dark field microscopy.

In certain embodiments, the illumination beam path may extend outside the imaging beam path.

As an alternative, the illumination beam path may extend inside the imaging beam path. Both arrangements are known in principle from the prior art and are therefore not explained in more detail.

In certain embodiments, the angle of incidence may be 0°. This has the advantage that existing mask registration apparatuses, which usually have an incidence angle of 0°, can be retrofitted with a dark field illumination. Furthermore, at least in the case of an illumination wavelength of at least 193 nm, a transmitted-light illumination is also conceivable.

In certain embodiments, the apparatus may have an evaluation unit for determining the geometry and/or the registration of the structure on the basis of the image information recorded using a recording device. Within the context of this disclosure, the image information is the light scattered from the edges of the structures or structure elements.

Furthermore, the apparatus may take the form of a mask registration apparatus.

In another aspect, disclosed is a method for measuring and/or registering structures on an object by means of a semiconductor lithography apparatus according to any one of the preceding embodiments comprises the following method steps:
determination of a reference image
acquisition of the image information generated by the illumination of the structure
comparison of the reference image and the acquired image information to determine the registration of the structure and its critical dimensions.

In particular, the image information from the scattered light from edges of the structure is relevant to the method described here. As explained further above, this may result in structures being able to be registered below the resolution capability of a conventionally used mask registration microscope.

In certain embodiments, the reference image can be determined by measurement.

In particular, an empirically determined scattering behaviour with objects corresponding to the measuring object can be used to determine the reference image by measurement.

In certain embodiments, the reference image can be determined by simulating the image information generated by the illumination of the structure.

In particular, the simulation of the reference image by applying edge operators can be based on simulated image information without scatter effects. An edge operator within the meaning of the disclosure is a function or operator which only determines the edges from an image which has light and dark areas, i.e. generates an edge image. Examples of edge operators may be a gradient operator or a Sobel operator known for edge determination in image processing.

Other aspects, embodiments, and advantages follow.

### DESCRIPTION OF DRAWINGS

Exemplary embodiments and variants of the disclosure will be explained in more detail below on the basis of the drawing. In the drawing:

FIG. 1 shows a schematic illustration of a state-of-the-art mask inspection microscope which can be used to perform the method disclosed herein,

FIGS. 2A and 2B show a detail of an exemplary embodiment,

FIGS. 3A and 3B show images of a structure from the prior art and using the disclosed embodiment and

FIG. 4 shows a flowchart of a method.

### DETAILED DESCRIPTION

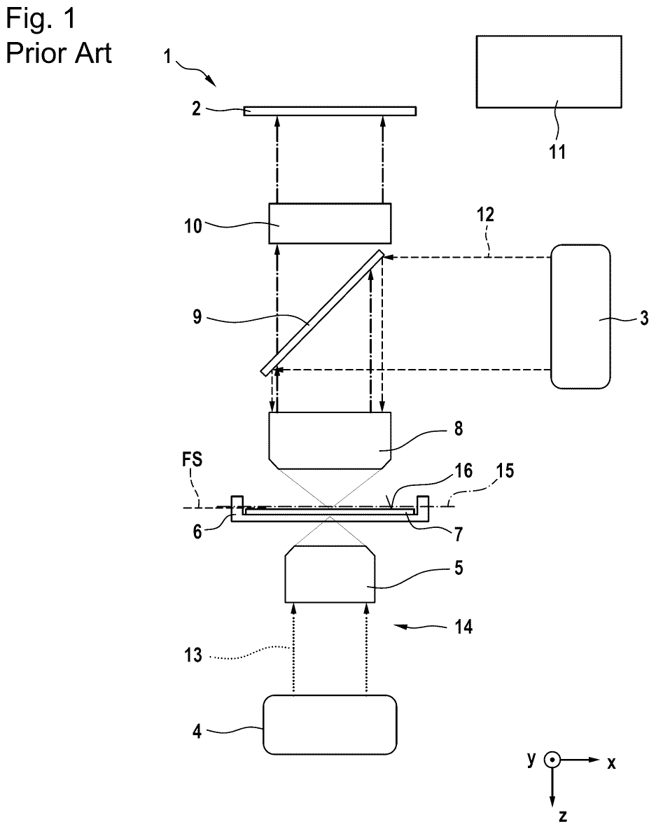

FIG. 1 shows a schematic illustration of a measuring device known from the prior art, which is designed as a mask inspection microscope 1 and serves to measure an object for semiconductor lithography in the form of a photomask or mask 7 in which the method disclosed herein can be used. The mask inspection microscope 1 comprises two light sources 3, 4, with a first light source 3 being designed to measure the mask 7 in reflection and a second light source 4 being designed to measure the mask 7 in transmission. The mask 7 is arranged on an object stage 6, which can position the mask 7 laterally (x-y-direction) and vertically (z-direction) in the sub-nanometre range. In this case, the positional accuracy can be in a range of better than 500 pm in particular, more particularly better than 250 pm.

During a measurement in transmission, the measurement light 13 of the illumination unit 14 comprising the light source 4 and an illumination optical element embodied as a condenser 5 passes through the condenser 5, which creates a desired light distribution on the mask 7. Then, the measurement light 13 passes through the mask 7, a magnifying imaging optical unit 8 and a tube 10, and arrives at a recording device 2 in the form of a CCD camera in the example shown. The semi-transparent mirror 9 arranged between the imaging optical unit 8 and the tube 10 is used for the measurement in reflection and has no influence on the measurement in transmission.

During a measurement in reflection, the measurement light 12 emitted by the light source 3 is reflected at the semi-transparent mirror 9 and subsequently passes through the imaging optical unit 8, with the result that the mask surface 16 is illuminated. Then, like in the case of a measurement in transmission as well, the illuminated mask surface 16 is imaged in enlarged fashion on the recording device 2 by way of the imaging optical unit 8.

The recording device 2, the object stage 6, the imaging optical unit 8 and the light sources 3, 4 are connected to a controller 11 which controls the interplay of the individual components 2, 3, 4, 6, 8 using an open-loop or closed-loop mechanism and which is also designed to process the captured images.

The so-called focal plane 15 is also depicted in FIG. 1. The focal plane 15 is the place at which a flat object such as the mask surface 16, for example, must be positioned in order to be recorded in the recording device 2 with maximum sharpness. In the z-direction, the location of this focal plane 15 depends on the distance between the recording device 2 and the imaging optical unit 8, and on the optical properties of the imaging optical unit 8. Thus, its location is defined by the configuration of the mask inspection microscope 1. Despite being called focal plane, the focus of the imaging optical unit 8 is not situated in said focal plane. Using terminology from geometrical optics, the focal plane in fact is a plane at the object distance which is assigned to a fixed image distance (determined by the properties and configuration of the imaging optical unit 6 and the recording device 2).

In order to determine the focal plane, the deviation of the position of a mask surface and the focal plane within the scope of a focusing is determined in the measuring device. For this purpose, the mask is positioned at a so-called focus stack starting point FS to start the focusing, from which position the focusing starts, regardless of whether an autofocus or a focus stack is used to determine the focal plane or the location of the sharpest image, which is also referred to as the best focus, which is relevant for the subsequent evaluation of the image.

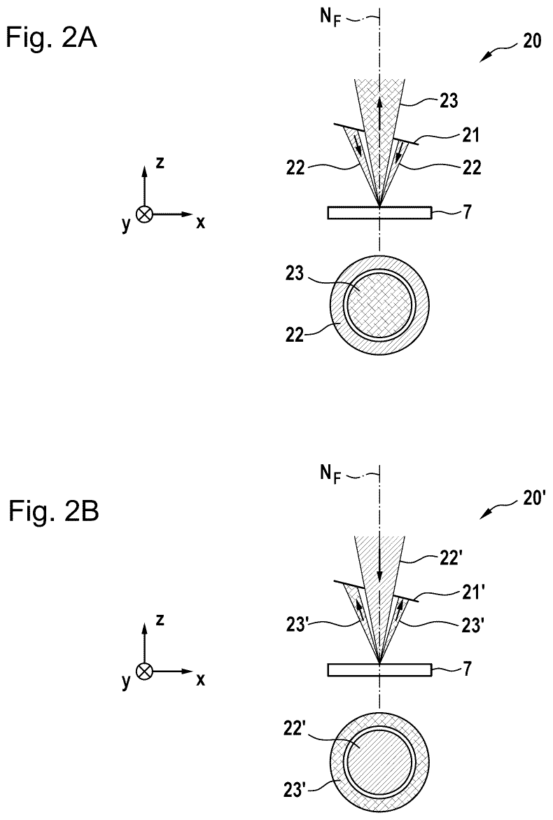

FIG. 2A shows a detail of a first embodiment and schematically illustrates beam path guidance of a dark field illumination 20. This can be integrated into a mask inspection microscope 1 illustrated in FIG. 1.

The illumination beam path 22, which is in the form of a continuous, rotationally symmetrical illumination, impinges on a subregion of the object in the form of a mask 7. The embodiment of the dark field illumination illustrated in FIG. 2A uses EUV light, i.e. light with a wavelength of 13.5 nm, which can only be imaged by reflective optical elements. The illumination beam path 22 is thus steered by a mirror 21 onto the object 7. For reasons of clarity, the portion of the illumination beam path 22 leading to the mirror has not been depicted. The direction of the beam path 22 is depicted by arrows in FIG. 2A.

According to this embodiment, the illumination beam path 22 is formed in such a way that the zeroth order of diffraction imaging the structure (not depicted) is not reflected into the imaging optical unit 8 of the apparatus in the form of a mask registration apparatus 1. The imaging beam path 23 illustrated in FIG. 2A includes the light scattered in the direction of the imaging optical unit 8 to the structural features of interest. Within the meaning of this disclosure, structure features of interest are for example edges of a structure, for example of a line or of a cross used as a marker.

The scattered light 23 is imaged onto the recording device 2 (FIG. 1) and thus corresponds to the image information of the imaging used for the registration.

The rotationally symmetrical arrangement of the illumination beam path 22 around the surface normal N_{F} of the object 7 is advantageous in that a z-displacement of the object 7 leads only to slight blurring of the imaged structures, i.e. for example leaves the position of the edges of a cross almost unchanged. A slight z-displacement thus has almost no effect on the centre of the cross, which is relevant to the registration, and so said centre is not displaced as a result.

FIG. 2B shows another embodiment of a dark field illumination 20′, which reverses the arrangement of the illumination beam path 22′ and the imaging beam path 23′. The illumination beam path 22′ is vertically incident on the mask 7 and the imaging beam path 23′ generated by the scattered light is imaged onto a rotationally symmetrical mirror 21′ and, from there, is imaged onto a recording device 2 (not illustrated) of the mask registration apparatus 1.

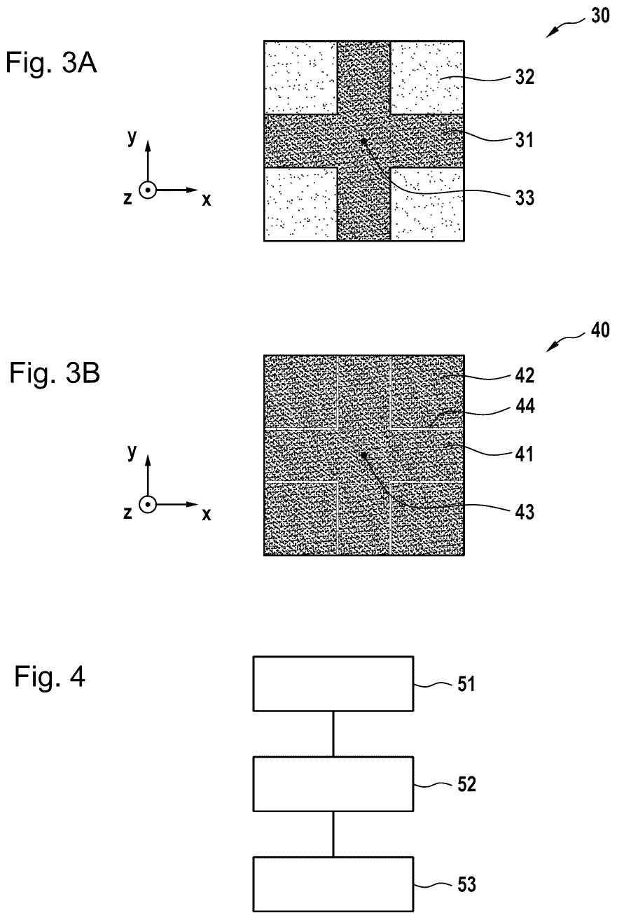

FIG. 3A shows an image 30 of a structure in the form of a cross 31, known from the prior art. The cross 31 is shown as dark in the image 30 because it absorbs more light than the environment 32, which is shown as brighter. To determine the position, i.e. to register the structure, the image 30 is evaluated and the centre 33 of the cross 31 is determined. This corresponds to the registration of the cross 31, which is used, for example, as a reference marker on a mask 7.

FIG. 3B, on the other hand, shows an inventive image 40 of a structure also in the form of a cross 41. In the image 40, the strongly scattering edges 44 of the cross 41 are shown as bright, whereas the less-scattering or non-scattering surfaces of the cross 41 and the environment 42 are shown as dark. From the brightly illustrated edges 44, in turn, the centre 43 of the cross is determined as the registration of the cross 41. As mentioned further above, a slight defocusing of the cross 41, i.e. with slightly blurred edges, would not change the position of the centre 43.

FIG. 4 shows a flowchart of a method for measuring and/or registering structures on an object of a semiconductor lithography apparatus.

In a first method step 51, a reference image is determined.

In a second method step 52, the image information generated by illumination of the structure 31, 41 is determined.

In a third method step 53, the reference image and the acquired image information are compared to determine the registration of the structure 31, 41 and its critical dimension.

Additional aspects, embodiments, and advantages are within the scope of the following claims.

### LIST OF REFERENCE SYMBOLS

1 Mask inspection microscope
2 Recording device, CCD camera
3 Light source for reflection
4 Light source for transmitted light
5 Condenser
6 Object stage
7 Mask
8 Imaging optics unit
9 Semi-transparent mirror
10 Tube
11 Controller
12 Measurement light in reflection
13 Measurement light in transmission
14 Illumination unit
15 Focal plane
16 Mask surface
20, 20′ Dark field illumination
21, 21′ Mirror
22, 22′ Illumination beam path
23, 23′ Imaging beam path
30 Image of the structure according to the prior art
31 Cross (structure)
32 Structure environment
33 Centre of the structure=registration of the structure
40 Image of the structure according to the disclosure
41 Structure
42 Structure environment
43 Centre of the structure=registration of the structure
51 Method step 1
52 Method step 2
53 Method step 3
FS Focus stack starting point
N_{F} Surface normals of the object

What is claimed is:

1. A semiconductor lithography apparatus for measuring and/or registering structures on an object by means of an illumination and an optics unit for illuminating the structure,
characterized in that
the illumination is in the form of a dark field illumination.

2. The apparatus of claim 1,
characterized in that
the object is in the form of a photolithography mask.

3. The apparatus of claim 1,
characterized in that
the apparatus is in the form of a mask registration apparatus.

4. The apparatus of claim 1,
characterized in that
the apparatus has an evaluation unit for determining the geometry and/or the registration of the structure on the basis of the image information recorded using a recording device.

5. The apparatus of claim 1,
characterized in that
the wavelength used for the illumination of the structure is in a range of from 5 nm to 100 nm.

6. The apparatus of claim 1,
characterized in that
the wavelength used for the illumination of the structure is in a range of from 100 nm to 300 nm.

7. The apparatus of claim 1,
characterized in that
the illumination is rotationally symmetrical about the surface normal (N_{F}) of the object.

8. The apparatus of claim 1,
characterized in that
the illumination is in the form of discrete illumination.

9. The apparatus of claim 1,
characterized in that
the illumination is in the form of continuous, rotationally symmetrical illumination.

10. The apparatus of claim 1,
characterized in that
the illumination beam path extends outside the imaging beam path.

11. The apparatus of claim 1,
characterized in that
the illumination beam path extends inside the imaging beam path.

12. The apparatus of claim 1,
characterized in that
the angle of incidence is 0°.

13. A method for measuring and/or registering structures on an object by means of a semiconductor lithography apparatus of claim 1, said method having the following method steps:
determination of a reference image
acquisition of the image information generated by the illumination of the structure
comparison of the reference image and the acquired image information to determine the registration of the structure and its critical dimension.

14. The method of claim 13,
characterized in that
the reference image is determined by measurement.

15. The method of claim 14,
characterized in that
an empirically determined scattering behaviour with objects corresponding to the measuring object is used to determine the reference image by measurement.

16. The method of claim 13,
characterized in that
the reference image is determined by simulating the image information generated by the illumination of the structure.

17. The method of claim 16,
characterized in that
the simulation of the reference image by applying edge operators is based on simulated image information without scatter effects.

18. The method of claim 13,
characterized in that
the image information includes generated scattered light from edges of the structure.

19. The method of claim 18,
characterized in that
the geometry and/or registration of the structure is ascertained on the basis of the detected scattered light.
